(19) United States
(12) Patent Application Publication
(10) Pub. No.: US 2009/0214828 A1
(43) Pub. Date: Aug. 27, 2009

(54) BLUNT TIP PRISM FILM AND METHODS FOR MAKING THE SAME

(76) Inventors: Vicki Herzl Watkins, Schenectady, NY (US); Dennis Joseph Coyle, Clifton Park, NY (US); Eugene George Olczak, Pittsford, NY (US); Scott Michael Miller, Clifton Park, NY (US); Nitin Garg, Guilderland, NY (US)

Correspondence Address: CANTOR COLBURN, LLP, 20 Church Street, 22nd Floor, Hartford, CT, 06103, US

(21) Appl. No.: 12/037,416

(22) Filed: Feb. 26, 2008

(51) Int. Cl. B32B 3/02; C23C 14/34

(52) U.S. Cl. 428/156; 204/192.34

(57) ABSTRACT

In one embodiment, a film can comprise a transparent substrate comprising a plurality of prism structures, wherein the prism structures have a blunt tip having a tip length of 250 nm to 2,000 nm. The film can be used in various applications, such as back light displays. In one embodiment, a method for forming a master for a film can comprise ion beam etching a diamond tip to form a blunt tip having a tip length of 250 nm to 2,000 nm, and forming negatives of prism structures into a master using the diamond tip.

### BACKGROUND

Brightness enhancing films can be used in a variety of applications, for example, interior illumination, light guides, and liquid crystalline displays (LCDs) such as those found in computer monitors. When employed in LCDs, one or more brightness enhancing films are used to increase the amount of light directed towards the viewer. This allows lower intensity, and thus less costly, bulbs to be used in the LCD. A backlight illuminates the liquid crystal display panel to desirably provide a uniformly intense light distribution over the entire plane of the LCD display panel. A backlight system typically incorporates a light pipe to couple light energy from a light source to the LCD panel. An array of diffusing elements can be disposed along one surface of the light pipe to scatter incident light rays toward an output plane. The output plane directs the light rays into and through the LCD panel. The backlight can use a light modulating optical substrate with prismatic or textured structures to direct light along a viewing axis, usually normal to the display and to spread illumination over a viewer space. The brightness enhancement optical substrate and diffuser film combinations enhance the brightness of the light viewed by a user and reduce the display power required to produce a target illumination level. This increase in brightness is customarily reported as the “gain,” which is the ratio of luminance using the brightness-enhancement film to the luminance without using the brightness-enhancing film, both measured on-axis, that is, in a direction perpendicular to the plane of the film towards the viewer.

It is also known to place two sheets of light directing film adjacent one another with their prisms oriented approximately perpendicular to one another to further increase the amount of light directed approximately normal to the axis of the display. While this construction effectively increases the amount of on axis light exiting the display, the resulting structure can exhibit uneven light transmission across the surface area of the display under certain conditions. This uneven light transmission is typically manifested by visibly apparent bright spots, streaks, or lines on the surface of the display; a condition caused by optical coupling between contacting, or very nearly contacting, surfaces of the adjacent sheets of light directing film, also known as “wet-out”. Wet-out occurs as a result of optical coupling between the prisms of one sheet and the smooth surface of the other. The optical coupling prevents total internal reflection from occurring along these peaks. The result is a mottled and varying appearance to the backlight. Such visibly apparent variations in the intensity of transmitted light across the surface area of the display are undesirable. This wet-out also occurs when any other film, such as a diffuser film, having an essentially smooth planar bottom surface, is placed on top of a prism film.

Additionally, for brightness enhancing films in a display that is intended for close viewing, such as a computer display, the cosmetic requirements are very high. This is because, when such displays are studied very closely or used for an extended period of time, even very small defects can be visible and annoying. Elimination of such defects can be very costly both in inspection time and discarded materials.

A second type of film used in LCDs is a diffusion film. As the name suggests, the diffusion film diffuses light directed to the viewer in order to reduce interference patterns such as Moire patterns. Such diffusers will hide many of the defects, making them invisible to the user. This will significantly improve manufacturing yield, while only adding a small increase in cost to the manufactured part. The disadvantage of this approach is that the diffuser will scatter the light and thus decrease on-axis gain. Therefore, a diffuser will increase yield but at the expense of some performance.

Another issue with the films is that the peaks are fragile and prone to scratching. As a result, the film leaks light, forming a visible defect.

Hence, there is a continuing need for optical film systems that have reduced visible defects.

### BRIEF SUMMARY

Disclosed herein are films, backlight displays, and methods of making and using the same.

In one embodiment, a film can comprise a transparent substrate comprising a plurality of prism structures, wherein the prism structures have a blunt tip having a tip length of 250 nm to 2,000 nm.

In one embodiment, a method for forming a master for a film can comprise ion beam etching a diamond tip to form a blunt tip having a tip length of 250 nm to 2,000 nm, and forming negatives of prism structures into a master using the diamond tip.

The above described and other features are exemplified by the following Figures and detailed description.

### BRIEF DESCRIPTION OF THE DRAWINGS

Refer now to the Figures, which are exemplary embodiments, and wherein the like elements are numbered alike.

FIG. 1 is a cross-sectional illustration of exemplary prismatic structures with blunt tips.

FIG. 2 is a cross-sectional illustration of an exemplary prism film.

FIG. 3 is a cross-sectional illustration of an exemplary prism film with variable prism spacing.

FIG. 4 is a perspective view of an embodiment of a film having a modulated prism path.

FIG. 5 is an overhead view of a section of modulated prism paths that are modulated in the w direction along the l direction.

FIG. 6 is a perspective view of the turning and diffusing of light beams, illustrating bow diffusion.

FIG. 7 is a prospective view of one embodiment of a backlight display system.

FIG. 8 is a cross-sectional view of an embodiment of a back light display system.

FIGS. 9 and 11 are exemplary graphical profiles of the peak heights h(j).

FIGS. 10 and 12 are histograms of the height variation over an entire substrate with the modulation for the profiles of FIGS. 11 and 13, respectively.

FIGS. 13(a)-(d) illustrate exemplary modulated surface height maps from profiles taken in the w direction, wherein each profile is 1.7 mm long with a 1 micrometer sample distance.

FIGS. 13(e)-(h) graphically illustrate exemplary autocorrelation functions for the surfaces illustrated in FIGS. 13(a)-(d), respectively.

FIGS. 14(a)-(d) graphically illustrate the power spectral density function of ƒ(x) for modulated prism surfaces of FIGS. 13(a)-(d) from profiles taken in the w direction, wherein each profile is 1.7 mm long with a 1 micrometer sample distance.

### DETAILED DESCRIPTION

As is explained above, even very small defects in an optical film can be visible and annoying. Even periodicity in the film can be identified by the unaided eye, and hence has been considered a problem itself. There is a need for films that retain luminance while being scratch resist. It has been unexpectedly discovered that by blunting the tips of the prisms, and/or rounding the valleys by a very slight amount, substantial improvement in scratch resistance is attained with minimal decrease in luminance. Desirably, the blunt tip size is close to the wavelength of visible and infrared light. In other words, very small blunt tips, e.g., 100 nanometers to 1,300 nm results in a large reduction in abrasion damage with the luminance is only slightly decreased (e.g., with 250 nm blunt tip there is 25% reduction of abrasion damage with 0.3% loss of luminance).

When prism tips are blunted using mechanical grinding, the blunted tips typically have a size of greater than 10 micrometers (μm) or equivalently 20% of a typical prism pitch. As a result, the luminance would decrease by greater than or equal to 10% (compared to a non-blunted film of the same composition and design, and formed in the same manner), which is unacceptably low.

Focused ion beam etching (“FIB”) uses a very fine ion beam. Depending upon the intensity of the beam, it can be used for cutting, welding, and imaging. Since ion-beam can be localized to sub-micron range, it is in theory capable to creating very precise cross-sections. Recent advancements in robotics, imaging, chemistry, etc., have enabled modifications such that cutting can be attained down to a previously unattainable level; e.g., to sizes of 200 nm to 500 nm. Using the focused ion beam etching, diamonds were produced having a small blunt length. The length could be less than or equal to 2,000 nanometers (nm), or, specifically, 250 nm to 1,500 nm, or, more specifically, 500 nm to 1,250 nm, and yet more specifically, 500 nm to 1,000 nm, and even more specifically, 500 nm to 800 nm. Using these diamonds, cylindrical molds with prismatic surfaces can be created by single-point diamond turning. The molds can then be used to produce films with prismatic surface textures by exposing a UV polymerizable coating on a film to UV light while in contact with the mold. For example, the films can have prismatic structures having a length “l_{b}” of the blunt tip “t_{b}” of 500 nm to 1,500 nm, or typically 1% to 3% of the pitch.

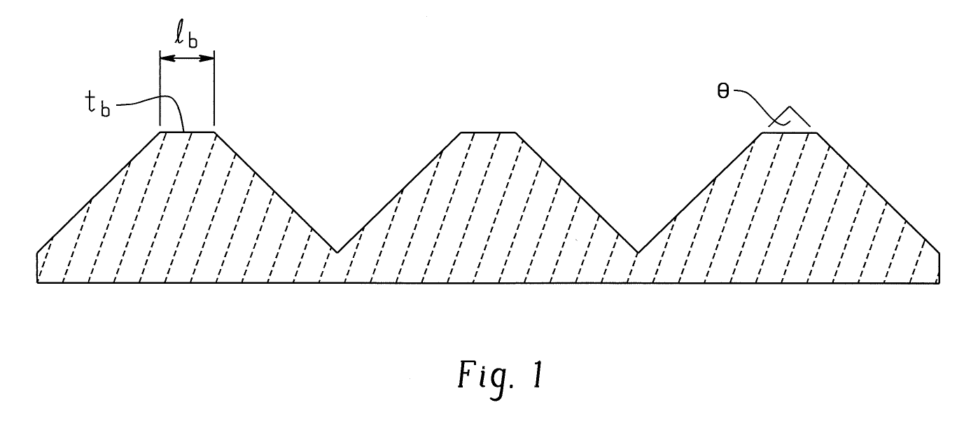

Optionally, the prismatic structures can have a valley that can be either sharp or have a rounded radius, e.g., of 100 nm to 1,000 nm. (See FIG. 1) The rounded valleys can be formed by an optional step in the mold-making process in which a thin layer of material (e.g., a metal such as nickel) is plated over the mold. In one embodiment, the film can comprise prismatic structures having a pitch of 30 micrometers to 400 micrometers, specifically, 30 micrometers to 75 micrometers, or, more specifically, 35 micrometers to 50 micrometers; and/or a virtual tip angle of the prism (Θ) of 70° to 120°, specifically, 80° to 100°; and a blunted tip (e.g., a flat tip having a length (e.g., of 500 nm to 1,300 nm), and that is parallel to the base of the prism).

It was unexpectedly discovered that, with blunt tips of 500 nm to 1,300 nm, the reduction in luminance was less than 3% (compared to a non-blunted film of the same composition and design, and formed in the same manner). In other words, with the control being 100%, the blunt tip films had a luminance of greater than 97%, and even greater than 98% with a 750 nm blunt tip.

In one embodiment, a film can comprise a transparent substrate comprising a plurality of prism structures, wherein the prism structures have a blunt tip having a tip length of 250 nm to 2,000 nm. The tip length can be 500 nm to 1,300 nm, or, specifically, 500 nm to 1,000 nm, or yet more specifically, 500 nm to 800 nm. The film can have a relative abrasion damage that is less than or equal to a 50%, as compared to the same composition film with the same characteristic except without blunt prism tips, and determined in accordance with Equation 2, or, specifically, a relative abrasion damage of less than to equal to 30%; and/or a luminance reduction of less than or equal to 5% as compared to a luminance of an equivalent film with sharp prism tips, or specifically, less than or equal to 2%. The prism can have a virtual tip angle of the prism (Θ) of 70° to 120°. The load required to create a visible scratch can be increased by greater than or equal to 20%, as is determined with the unaided eye. Each prism structure can has a lateral modulation in the w direction of ±2% to ±20% of an average pitch of the prisms. The prism structures can also have a valley that can be either sharp or have a rounded radius, e.g., of 100 nm to 1,000 nm.

In one embodiment, a method for forming a master for a film can comprise ion beam etching a diamond tip to form a blunt tip having a tip length of 250 nm to 2,000 nm, and forming negatives of prism structures into a master using the diamond tip. Each prism structure can have a lateral modulation in the w direction of ±2% to ±20% of an average pitch of the prisms. Prism structures can be formed into the surface of a transparent substrate by contacting the master with a transparent substrate to form a light directing film having prism structures with a blunt tip having a tip length of 250 nm to 2,000 nm.

The process of producing the blunt tip film comprises forming a master (e.g., a negative of the desired film). The master can be formed from a positive of the film or directly from an ion beam etched cutter (e.g., diamond tip). For example, an argon ion etch using a focused ion beam can be employed. Optionally, the ion beam can have a beam diameter of less than or equal to 20 nanometers, e.g., for precise feature control

As is explained above, even very small defects in an optical film can be visible and annoying. Even periodicity in the film can be identified by the unaided eye, and hence has been considered a problem itself. There is a need for films that retain gain while avoiding wet-out and visible defects. Wet-out has been reduced, and even eliminated, by employing a periodic, sinusoidal structure wherein the prism peak is varied and highest prism peak height appears periodically (and sometimes in clusters or zones) at an interval, measured in the w direction, of greater than or equal to five times the distance between prism peaks (i.e., five times the average pitch wherein the average is determined over a sample length in the w direction of 0.5 millimeters (mm) to 100 mm). The interval length in the l direction over which the highest prism height is varied is equivalently greater than or equal to 5 times the circumference of the master tool from which the films were made, where a typical circumference would be 0.5 meters to 1.0 meters. Although this periodic high point solved the wet-out problem, it introduced a visible periodicity into the film which manifested itself as a visible streakiness. It has unexpectedly been discovered that, with the combination of the sinusoidal periodicity of peak height in h direction and a slight lateral modulation of peak height in the w direction (both occurring along a prism length that is nominally in the l direction (see FIG. 4)), wet-out issues have been addressed while avoiding streaking, substantially retaining and minimizing production loss and waste. With a mere ±2 micrometer lateral modulation in combination with a substantially sinusoidal height modulation which is periodic wherein the peak height modulation frequency is sufficient to avoid optical coupling between adjacent collimating films, wet-out can be substantially reduced or eliminated while avoiding streakiness.

In some embodiments the backlight display can comprise: light source(s) and optical film(s). The display can comprise diffuser(s), reflector(s) (e.g., pattered reflector(s)), and/or light guide(s). The reflector(s) can be disposed on a side of the light guide opposite the optical film(s). The diffuser(s) can be disposed on one or both sides of the optical film(s), wherein the optical films can be disposed such that the prisms structures of one film are oriented at a direction perpendicular to the prism structures of an adjacent optical film (e.g., as is illustrated in FIG. 6).

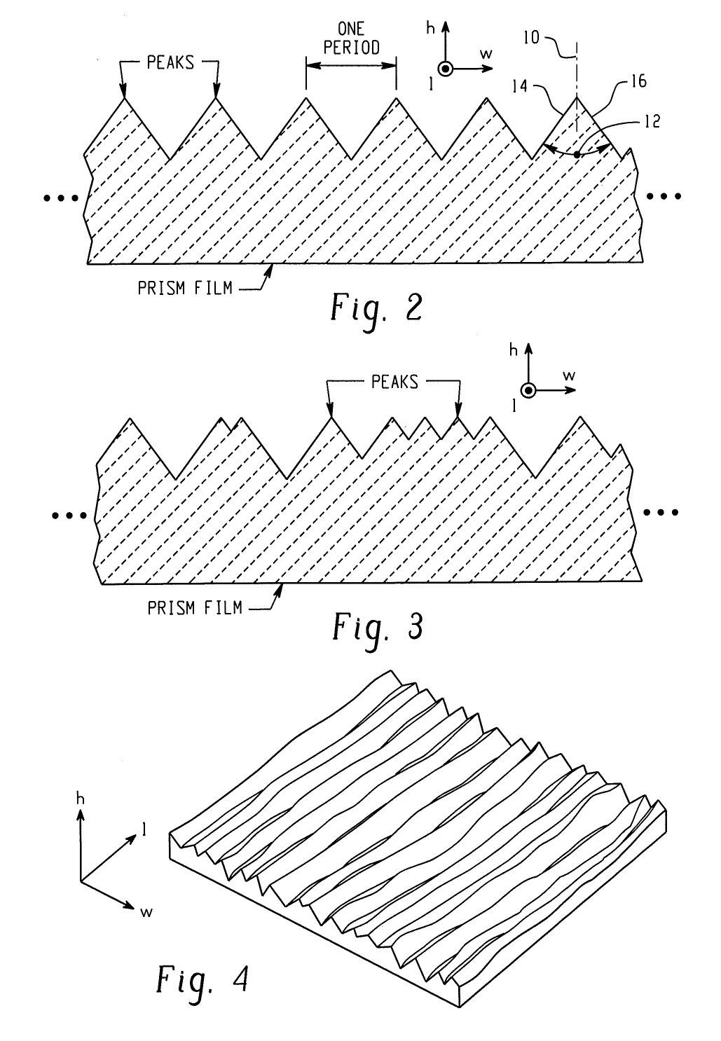

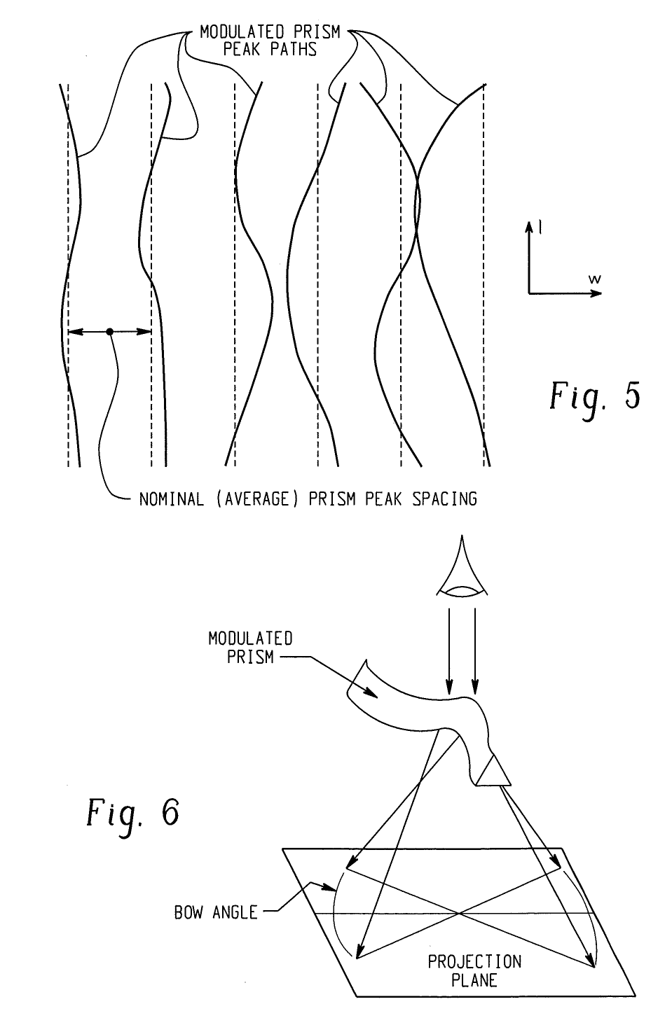

As shown in FIG. 2 the cross section a prior prism film reveals an upper surface that is corrugated (i.e., the surface is comprised of a linear array of prism structures), each prism having straight facets, which in this illustration, are symmetrically disposed around a peak (maximum in h) for each prism in a direction w that is a lateral direction for the prism film. The prisms are described as a linear array since the distance between adjacent peaks has a fixed pitch in the w direction and the pitch is held constant along the length of each prism. The pitch is the spacing in w between adjacent peaks. The length dimension is defined along a direction “l” that is normal to the page in FIG. 2. In FIG. 2 the prisms each have straight sides with a peak angle 12 that is symmetric about a line 10 though the peak in the h direction. The peak angle 12 includes the total included angle between the left and right facets (14, 16, respectively). If each facet where curved the peak angle would be the angle between the lines tangent to each facet where the facets meet at the peak.

In a brightness enhancement film the peak angle can generally be 85 and 120 degrees. The most popular design has a left facet slope of +45 degrees (change in h over change in w) and a right facet slope of −45 degrees. In a turning film the peak angle the peak angle can be 50 to 80 degrees. In a front lighting film the peak can be asymmetric and the peak angle can be 0 to 30 degrees. In some cases the peaks are rounded or blunted (flat peaks) across a width of less than or equal to 2 micrometers (μm), e.g., to improve abrasion resistant. This tends to exacerbate the wet-out problem, but can be useful all the same.

Brightness enhancement films typically have a thickness (in an h direction orthogonal to w and l) of 12 micrometers to 250 micrometers. In is understood that the film can be a thicker substrate (up to several millimeters in thickness), more typically identified as a plate. In the following discussion the term film will be used throughout to identify the optical device regardless of thickness, and since brightness enhancement is not the sole application, prism film and even optical film may be used generally refer to the substrate.

FIG. 3 shows an example of a substrate (e.g., a prism film) with variable prism spacing. Note that in contrast to the structure in FIG. 2, the distance between adjacent prism peaks is not constant. By averaging the distance between adjacent peaks over a number of peaks one can define an average pitch. The average can vary across a substrate, i.e., if, for example, ten or less adjacent peaks are used to define an average and the substrate surface comprises one hundred or more prisms (also called prism structures), the average pitch can be designed to vary. It is noted that this average is the average for the profile sample being examined, wherein the length sample in the w direction is between 0.5 mm and 100 mm.

Optionally, the peak's position for each prism can (individually) vary in the lateral w direction along the 1 length direction for each prism peak as shown in FIG. 4. This variation is defined as lateral modulation. The modulation comprises modulating the structures (e.g., prismatic structures, and so forth) of an optical film from the nominal linear path (non varying) in a lateral direction w (direction perpendicular to the height), along the length l, by using a waveform or waveforms that are a function of l that have a nonrandom, random (or pseudo random) amplitude and/or period, wherein, here, amplitude refers to the maximum excursion perpendicular to a straight line fit to the modulated prism path. For each prism this straight line will be substantially parallel to l. The amplitude can be less than the average pitch or larger that the average pitch. As noted above, an amplitude of 4 micrometers (e.g., plus or minus 2 micrometers from center), is sufficient to eliminate streakiness. The modulation can be less than or equal to 110 micrometers, or, specifically, less than or equal to ±5 micrometers, or, more specifically, less than or equal to ±2 micrometers, or, specifically, greater than or equal to ±2 micrometers and less than or equal to +10 micrometers for an average pitch of 37 micrometers. The maximum modulation can be 2% to 100%, or, specifically, 5% to 90%, or, more specifically, 2% to 50%, or, more specifically, 10% to 25%, of the average pitch with larger modulations having the disadvantage of reduced brightness. In some embodiments, the modulation is 70% to 95%, or, specifically, 75% to 90% of the average pitch. For example, a film can have a height modulation of 0.5 micrometers (μm) to 1 μm, and/or a lateral modulation of ±5% to +100% of the pitch.

Examples of lateral modulation waveforms include sinusoidal waveforms where the sinusoid has a random phase, frequency, or amplitude, or a combination comprising at least one of the foregoing. Another example is a waveform where the signal is produced by filtering a random noise waveform (uniform, Gaussian, or pink noise, are examples) with a band pass, low pass, or high pass filter. The signal can be continuous (analog), discrete (sampled), or a combination of both. The lateral modulations waveform or neighboring prisms can include interactions between the prisms. For example, a two dimensional filter can be applied such that the random wave forms are filtered along the length l and also include numerical input from the noise waveforms of adjacent prisms. One such implementation would be to low pass filter the noise waveforms in the l direction and high pass filter between noise waveforms in the w direction. By filtering in two dimensions the visible grain of the surface can be controlled in a very general way to avoid undesirable spatial frequencies. The filters can be discrete or continuous or a combination of both. In the example above the w direction filter would most likely be discrete, with the l direction filter as least approximately continuous. The wavelength cut offs for the various filters that can be applied are 10 micrometers to 10 millimeters. This range can also be applied to sinusoidal components that are used for lateral modulation.

The macroscopic blur function of a typical prism film with straight facets results in a double image with the image doubling effect increasing as function of the distance between the prism array surface and the object. Due to the various modulation paths in the randomized structure introduced here, there is an additional component to the blur function that is due to curvature of the paths. The effect is that of a rotation of each of the split images around an arc. This is called “bow diffusion” due to the resemblance that the blur function has to a bow tie. (See FIG. 6) Generally, increased slope in the path results in increased blur.

Although modulation of greater than 5% or the average pitch could be employed to address moiré effects, it was not known or believed that lateral modulation could be employed in combination with height modulation (modulation in peak height as a function of l or between different prisms) due to a periodic sinusoidal waveform, to reduce or eliminate periodicity induced streakiness while preventing optical coupling.

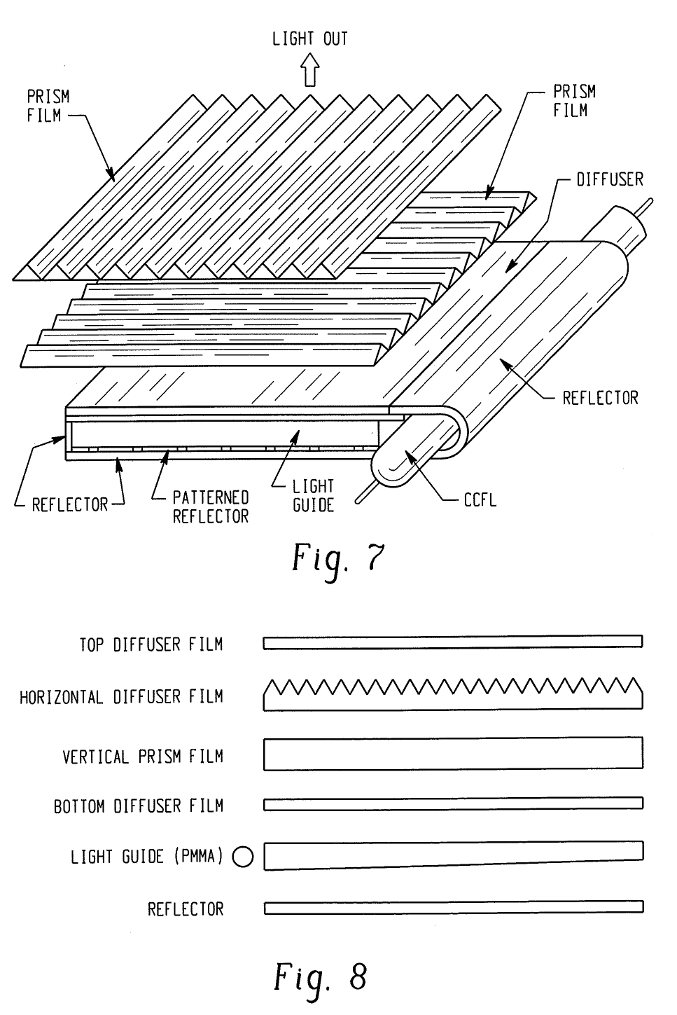

FIGS. 7 and 8 depict exemplary backlight displays. Light enters the display from the light source (e.g., cold cathode fluorescent light (CCFL); one or more light emitting diodes might also be used) and passes through the light guide where it is reflected toward the diffuser. The light passes through the diffuser and into the prism films where it is collimated and directed out of the display (see light out arrow). Light that is directed back toward the diffuser is reflected by the reflector back toward the prism film. The bulk statistical properties of such a film are characterized by parameters such as optical gain and viewing angle. The prism films shown in the figures may be designed with the present disclosure, i.e. the display backlight can comprise one or more prism films.

One method for characterizing surfaces is the autocorrelation function. Let the height of the surface along a cross section be given by ƒ(x) where x is the position along the cross-section. The auto correlation function of ƒ(x′) is given by

$${c}_{f} ( {x}^{′} ) = {\int }_{- ∞}^{∞} f ( x - {x}^{′} ) f ( x ) d x \qquad Equation 1$$

where x′ is a shift in coordinate x. The autocorrelation function c_{ƒ}(x′) is symmetrical x′ equal to zero and has a Fourier transform relationship with the power spectral density of ƒ(x).

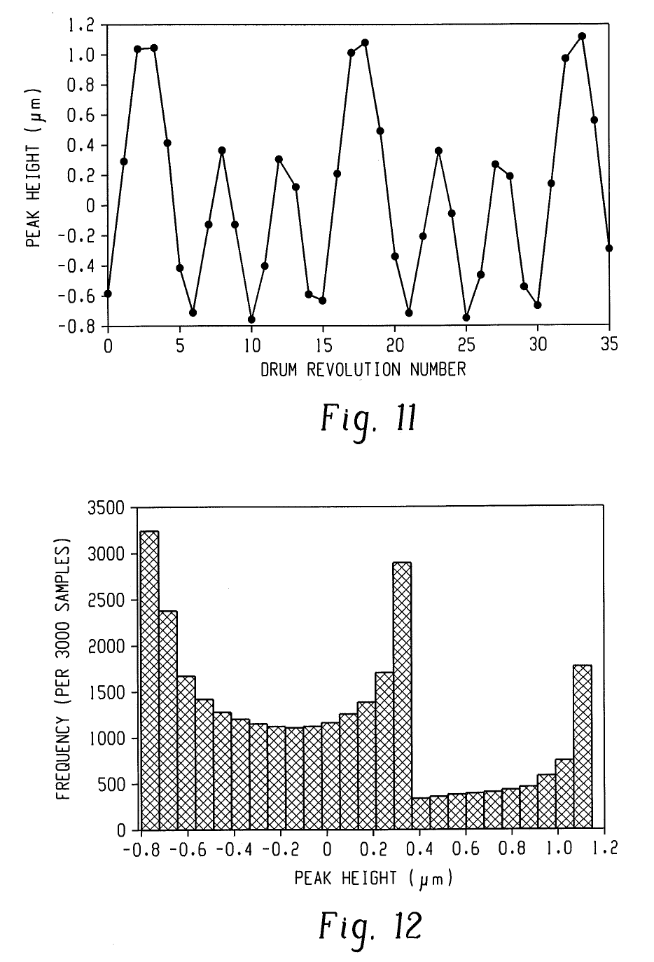

The autocorrelation is used in surface metrology to categorize the different types of surfaces. The autocorrelation function always has a maximum value of c_{ƒ}(x′) at x′=0. Random surfaces, such as diffusers, have the characteristic that c_{ƒ}(x′) will rapidly attenuate as x′ is increased above zero. For purely periodic surfaces c_{ƒ}(x′) will oscillate to it's maximum value at an interval that corresponds to the nominal period of the structure (See FIGS. 12(a)-(h), wherein (a) correlates with (e), (b) with (f), and so forth) This occurs for integration over negative infinity to positive infinity; finite profiles of periodic surfaces will have a similar oscillations in c_{ƒ}(x′) that tapers off linearly to zero at a length that is equal to the length of the sample).

One way to quantify the randomness of a surface is using the autocorrelation length of c_{ƒ}(x). The autocorrelation length (L_{c}) is the distance from x′ at which c_{ƒ}(x′) first decreases below a threshold. The threshold is a fraction of c(x′) at x′=0, typically e⁻¹ (0.37). Generally speaking, the shorter the correlation length, the more random the surface. For a surface whose topography consists of pure white noise c_{ƒ}(x′) reduces to a delta function and L_{c}=0.

A larger correlation length means that the surface is less random than a surface with a smaller correlation length. A more detailed discussion of the autocorrelation function is provided in David J. Whitehouse, Handbook of Surface Metrology, IOP Publishing Ltd. (1994), p. 49-58.

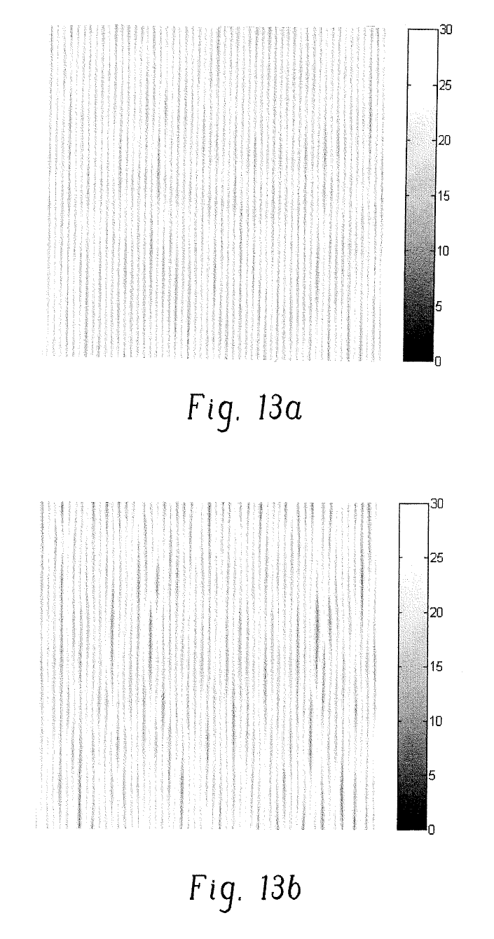

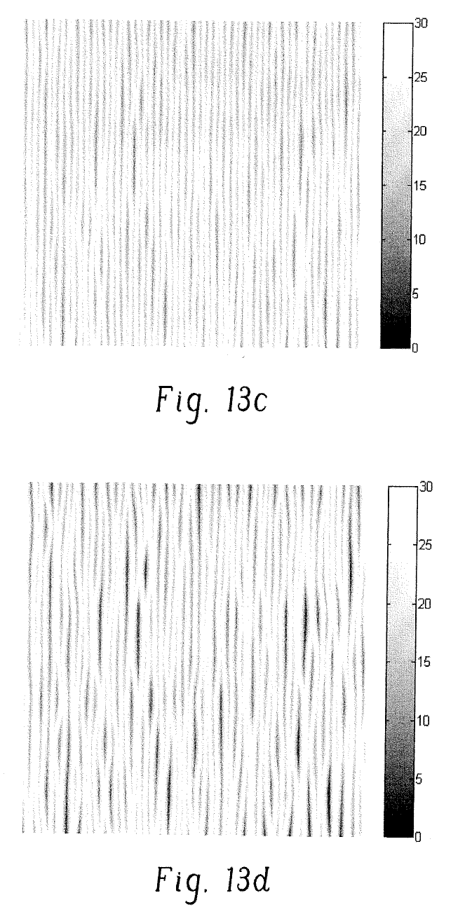

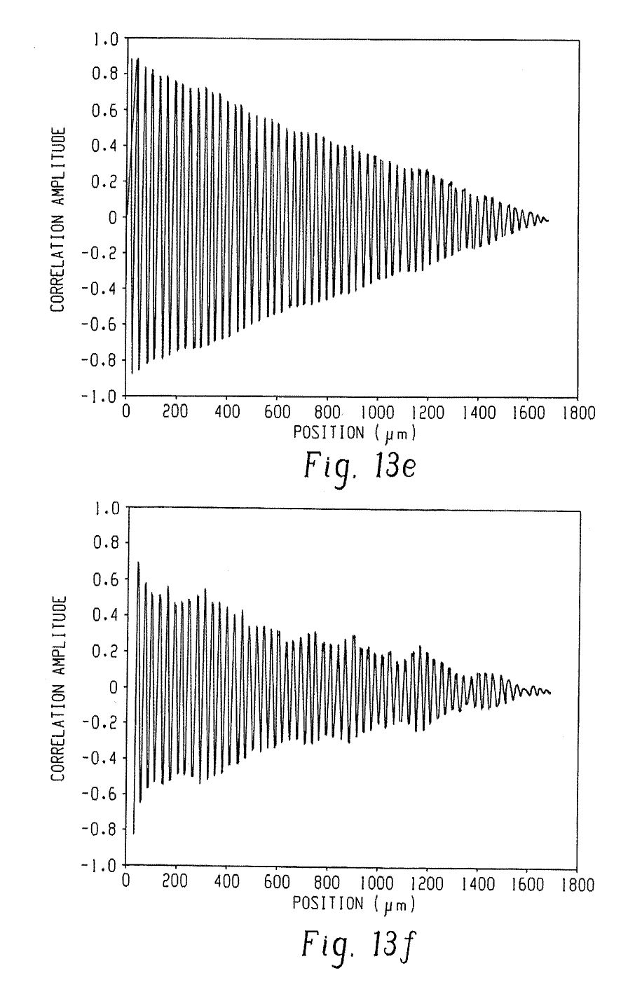

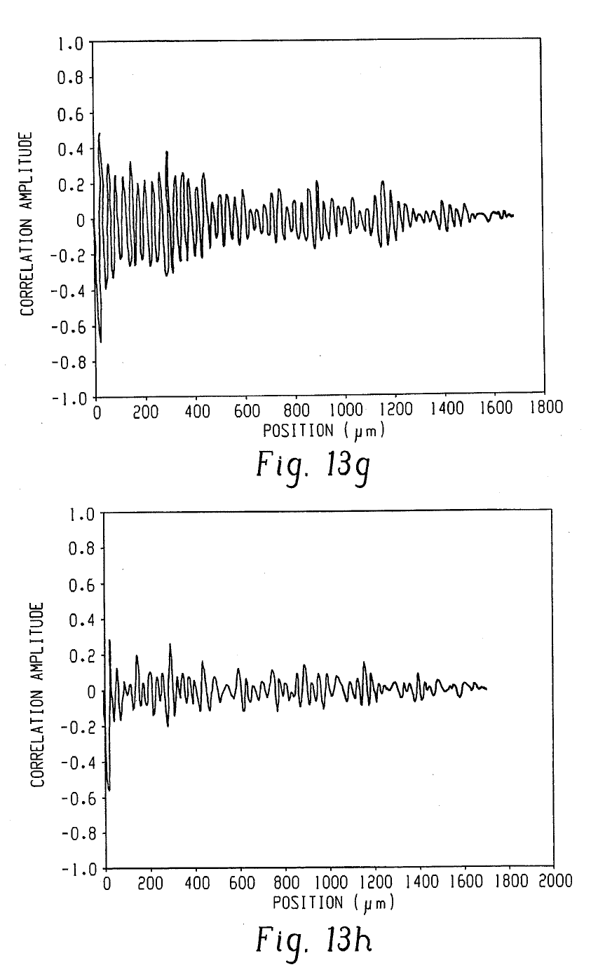

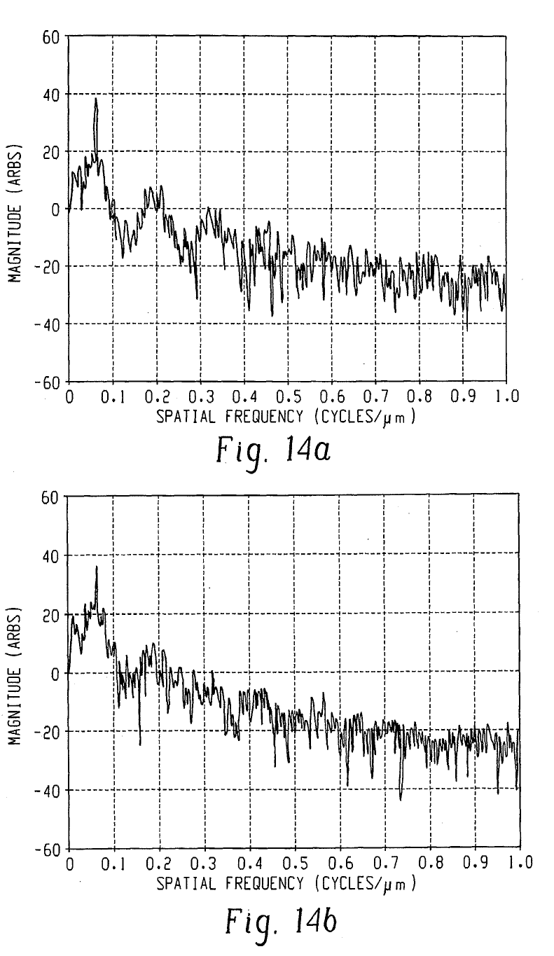

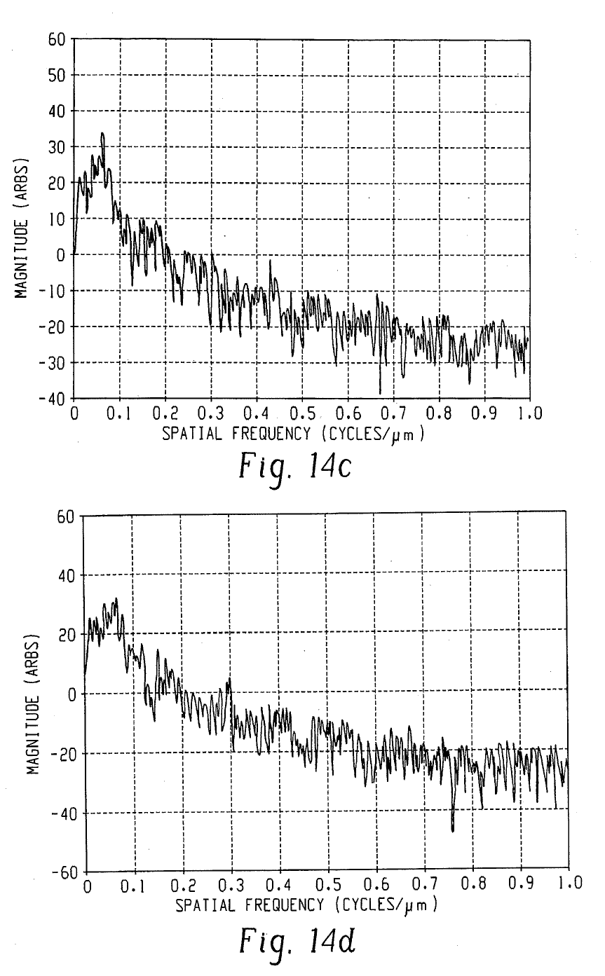

The examples in FIG. 13 show autocorrelation function analysis for a 1.7 millimeter by 1.7 millimeter (mm) model of film examples with increasing random lateral modulation for each example from left to right. Each example is sampled in a 1 micrometer by 1 micrometer grid and the auto correlation function is evaluated for a 1.7 millimeter long profile taken from the w direction (height h as a function of w). The analysis is performed using the MATLAB analysis software standard function xcorr.m provided with MATLAB release “R12”. The “coeff” option is used to provide a normalized output for zero lag (the initial value).

Note that the autocorrelation function oscillates at an interval equal to the average pitch of the examples (wherein the present examples all have 37 μm average pitch, thought the present application is not limited to such a pitch). The envelope of the oscillations drops off nearly linearly for FIG. 13(e) (FIG. 13(h) with the least lateral modulation) as a function of position. All the other examples have envelopes that drop to lower values more rapidly as a function of position (increasingly so toward FIG. 13(h)). This drop is due to the increased randomness caused by increasing random lateral modulation.

In some embodiments, the value of the autocorrelation function for the three-dimensional surface of the optical substrate for a 1.7 mm sample drops to less than or equal to 1/e (1/2.7183) of its initial value in a correlation length of less than or equal to 0.5 millimeter (mm). In still other embodiments, the value of the autocorrelation function drops to 1/e of its initial value in less than or equal to 0.1 mm. The 1.7 mm sample scans can be taken from a lateral profile at any location on a film or other optical substrate that employs the technology.

The correlation length is related to the reduction of moiré artifacts. As noted, smaller correlation length indicates a more random surface than a larger correlation length, and this smaller correlation length also relates to greater diffusion and the reduction of moiré artifacts. Because the three-dimensional surfaces of the substrates (FIGS. 13 (b)-(d) are highly irregular, as indicated by the low correlation length, the substrates can be effective to reduce moiré artifacts.

As noted above, even sight lateral modulation is enough to mask the undesirable the visual appearance that is caused by substantially periodic height modulation patterns. The height variation can have a very long period: with a wavelength that is several times that maximum length of the prisms in the l direction of a particular substrate. This can be physically manifested as long wavelength variations in the height of a cutting tool around a drum used as a master for the films. For an illustration purposes, the l maximum length of a substrate is equivalent to one circumferential pass around the outer diameter of a mastering drum (though this can change in other cases). In this case every prism is equivalent to a ring around the drum and can be identified by drum revolution number, distance along l is equivalent to the position in rotation the drum axis (t, with units of radians).

The purpose of the height variation is to minimize optical coupling. This is achieved by creating height variations such that the majority of prisms do not experience optical coupling. This can be achieved by keeping the majority of prism peaks at least 0.5 micrometers below the highest prisms' peak height for any profile of a substrate as measured in the w direction (0.5 millimeters to 1.7 millimeter being a suitable measurement width—a diamond stylus profilometer with a tip radius of less than 2 μm can be the instrument to verify the height variation). This distance has been found to substantially avoid contact with the lower prisms, even in the presence of a warped substrate. The net effect is that the density of contacting prisms is substantially reduced and the optical coupling effect is less prominent.

The following is an example of a waveform for the height of modulation, h(l). Here t is related to l by a drum diameter, d, such that for each j^{th} ring around the drum (nominally separated from each other by pitch p), l is equal to t times d. Note that since each ring corresponds to an individual prism the j^{th} ring is equivalent to the j^{th} prism. Let the height for each peak at t=0 for each of a number of adjacent rings be identified by a ring number j such that h is a function of j or just h(j)). The height modulation can be continuous along l or discrete from ring to ring, or a combination of both. Define a period=15.5; and a beta=4, so that

$$h ( j ) = 0.25 cos ( \begin{matrix}{( \frac{π j}{period} )}^{beta} + {( \frac{3 π j}{period} )}^{beta} + \\ {( \frac{5 π j}{period} )}^{beta} + {( \frac{7 π j}{period} )}^{beta}\end{matrix} )$$

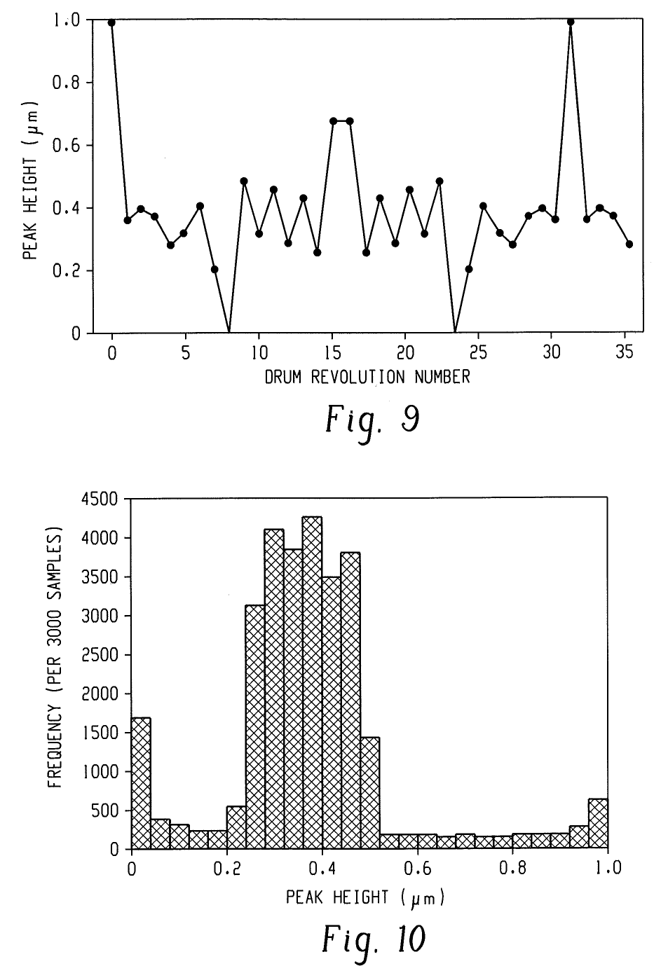

Here beta is a non-linear scale factor that provides for a skewed distribution in height, cos is the cosine function. A profile of the peak heights (h(j)) is given in FIG. 9. Note that these heights are defined with h=0 defined at the height of the shortest peak or a nominal reference height. A histogram of the height variation over an entire substrate with this modulation is given in FIG. 10.

Another example of h(j), as illustrated in FIG. 11, is as follows:

h(j)=a⁰+a¹ cos(jw)+b¹ sin(jw)+a² cos(2jw)+b² sin(2jw)+a³ cos(3jw)+b³ sin(3jw)+a⁴ cos(4jw)+b⁴ sin(4jw)+a⁵ cos(5jw)+b⁵ sin(5jw)

wherein (with the units of height being micrometers):
a⁰=−0.001667
a¹=0.1807
b¹=0.3245
a²=−0.2006
b²=0.3085
a³=−0.58
b³=−0.005871
a⁴=0.003714
b⁴=0.1724
a⁵=−0.0004167
b⁵=−0.0016 and
w=0.4516
   As shown in FIGS. 11 and 13, this height modulation also has the property of providing a distribution of peaks heights that keeps the majority of peak height on a level of 0.5 μm or more below the highest peaks. Although the waves are periodic, a random waveform formed with similarly large component wavelengths (i.e., spatial frequency content) can achieve a similar effect as long as the distribution is skewed to the majority of the peaks being greater than or equal to 0.5 μm below the highest peak height (i.e., the median height is at least 0.5 μm less than the tallest peak height). If the high peaks occur in a cluster (adjacent peaks with a height within 0.25 micrometers of the maximum) it is desirable that less than or equal to 3 peaks (or, specifically, 2 peaks) occur in each cluster and that each cluster is separated by greater than or equal to 5 lower peaks, or, specifically, greater than or equal to 8 lower peaks, (for any w direction profile). This separator helps to avoid visually objectionable large regions of wet-out. The occurrence of cluster does not have to be limited to strictly periodic.

The actual surface of the substrates, which can have characteristic dimensions of up to 4 meters in the w and l dimensions, independently, and have good surface roughness (e.g., the facets are smooth with a an average surface roughness, Rₐ, less than or equal to 4 nanometers (nm), desirably, less than or equal to 1 nanometer), can be generated in accordance with a number of processing techniques. These processing techniques include photolithography, gray-scale lithography, microlithography, electrical discharge machining and micromachining using hard tools to form molds or the like for the surface model described above.

For example, the method of making the substrates can be by mastering, electroforming, and mold forming. Photolithographic mastering can be used to directly laser write to a photoresist, a gray scale mask, and/or a series of halftone masks that can be tiled. The photoresist can be directly removed by the laser photons or used as a precursor to an additional process step, such as reactive ion etching (RIE). Alternatively, or in addition, the geometry might be mastered using hard tools, such as a single point diamond tool on a multi-axis (e.g., five axis) mill. The master will generally be made as a negative. The substrate of the master can be glass, (fused silica for example), metal (copper or nickel for example) or plastic (polycarbonate for example). The master can be used to mold plastic parts directly or used in electroforming.

Electroforming can be in one multiple (e.g., two) stages, wherein the master is a positive if only one stage is used. The master can be coated with a thin metal coating (especially if the master is not inherently conductive). A “father” electroform is created by electro-depositing nickel (or another material) on the master. This replica is again electroformed to create a “daughter” that is used to mold the plastic parts.

The object that is used to mold the device (films) is referred to as the mold. The mold can be in the form of a belt, a drum, a plate, or a cavity. The mold can be tiles from a plurality of masters or electroforms. The mold can be used to form the structures on a substrate through various processing embossing (e.g., hot embossing of the substrate), calendaring (e.g., cold calendaring of the substrate) and/or through the addition of an ultraviolet curing or thermal setting material in which the structures are formed. The mold can be used to form the film through various techniques such as injection molding, vacuum forming, and so forth. The substrate or coating material can be any organic, inorganic or hybrid optically transparent material and can include suspended diffusion, birefringent, and/or index of refraction, modifying particles.

The optical substrate so formed can be formed with an optically transparent material with an index of refraction of 1.1 to 3.0 and more particularly with an index of refraction of approximately 1.45 to 1.7.

In the following examples, the abrasion resistance of the film was characterized using a modification of the oscillating sand test, ASTM F735-94 (2001), in which the test method was altered to use 4 millimeter (mm) glass beads instead of sand. A 13.5 gram (g) quantity of glass beads was placed on top of the prismatic surface of the film in a plastic container and oscillated at 180 revolutions per minute (RPM) for 2 minutes. The on-axis transmission of light through the film was measured with BYK Gardner “Haze-Gard-II” hazemeter before and after subjecting the film to oscillating bead abrasion. The prismatic surface is positioned against the sample port so that the collimated light passes through the back planar side of the prism film and tries to exit out to the integrating sphere and detector through the prisms. For a theoretically perfect prism all of the collimated light is retro-reflected back to the light source and the percent transmission is zero. For typical prism films with sharp, undamaged prisms, the percent transmission is typically about 4%. Abrasion damage causes greater transmission through the film, so that the change in percent transmission quantifies the abrasion damage. We further define a relative abrasion damage, AD_{R}, as the abrasion damage of a sample of interest (ΔTₛₐₘₚₗₑ) relative to the abrasion damage of a known reference sample (ΔT_{ref}). The procedure is as follows: films of interest are chosen, the percent transmission of all films is measured (% T₀), the films are then abraded according to the above-described oscillating bead test, the percent transmission of all abrasion-damaged films are measured (% T_{AD}), the change in % transmission is computed for each film by the formula ΔTₛₐₘₚₗₑ=% T_{AD}−% T₀. The relative abrasion damage is then computed for each film by taking the ration of the sample's ΔT to that of the chosen reference sample; see Equation 2:

$${AD}_{R} = \frac{{( \% {T}_{AD} - \% {T}_{0} )}_{sample}}{{( \% {T}_{AD} - \% {T}_{0} )}_{ref}} = \frac{Δ {T}_{sample}}{Δ {T}_{ref}} \qquad Equation 2$$

Any convenient sample can be chosen as a reference. If one wanted to quantify the effect of tip blunting on abrasion damage for a given material, one would choose a sharp-tip prism film of that material as the reference so that AD_{R} quantified the relative abrasion damage of a blunt tip compared to a sharp tip. As defined, smaller AD_{R} means less abrasion damage and is desired. Equivalently, smaller AD_{R} means that the film is more abrasion-resistant. With the blunt tip films, a relative abrasion damage of less than 50% was readily attainable (as compared to the same composition film with the same characteristic except without blunt prism tips (with sharp tips), and determined in accordance with Equation 2; e.g., with a tip blunting of only 750 nm or 2.0% of prism pitch. Specifically, a relative abrasion damage of less than or equal to 40% was attained, and even less than or equal to 30%.

Scratch resistance of films was also characterized by making a series of scratches on the prismatic surface using a 2.5 mm radius stylus and varying loads. The films were visually inspected on an operating liquid crystal display backlight to determine which scratches were visible, wherein the visual inspection is with the unaided eye in a dark room, from a viewing distance of 0.1 to 1 meters at a variety of angles chosen to make defects readily apparent, wherein the unaided eye excludes the use of optical devices for magnification with the exception of corrective lenses needed for normal eyesight. The lightest load that created a visible scratch is deemed the threshold load for visual damage. A greater threshold load indicates a film with greater scratch resistance, or, a film with less abrasion damage. Thus as defined, larger threshold load means less abrasion damage for a given load and thus is desirable.

On-axis luminance was measured using a Microvision SS220 display analysis system (commercially available from Microvision, Auburn, Calif.). A commercial direct-lit 19″ diagonal backlight was used as a light source, and each test prism film was placed on top of the diffuser plate and bottom diffuser of this backlight, with the prisms oriented running horizontally, and the on-axis luminance measured and averaged over 13 points spanning the area of the film. The on-axis luminance of a reference film was used to define the relative luminance of the test samples as the ratio of luminance of the test divided by the luminance of the reference.

### EXAMPLES

### Example 1

### A Light Directing Film Comprising Peaks that are Sharp not Blunt

Light directing film was prepared by curing a UV curable acrylate coating between the surface of a micropatterned mold and a 175 micrometer thick flat polycarbonate film. The coating was that described in Example 1 of U.S. Published Application No. 2007/0082988; i.e., 60 parts by weight (pbw) brominated epoxy acrylate EBECRYL 51027, 40 pbw phenylthioethyl acrylate, 0.25 pbw acrylic acid, 0.25 pbw of SILWET 7602 silicone-polyethyleneoxide copolymer, 0.5 pbw IRGACURE 819 photoinitiator, and 0.25 pbw palmitic acid, and is hereafter designated as “Resin A.” The mold was constructed so that the surface of the cured coating comprised prisms with sharp peaks having an essentially 0 nanometer (nm) radius. The film was tested for abrasion damage and luminance as described above. This film was chosen as a reference so that the AD_{R} and relative luminance are 100% by definition. The threshold load for visible scratch damage was 0.3 g.

### Example 2

### A Light Directing Film Comprising Blunt Peaks 500 nm Wide

A micropatterned mold was prepared using a single point diamond tool with a blunt tip produced by taking a conventionally mechanically lapped sharp-tip diamond tool and subjecting it to a highly-focused argon-ion beam to etch its tip flat so that the tip was blunted to an approximately 500 nm wide flat surface.

A light directing film was prepared using the materials and by the method described in Example 1 using a mold constructed so that the surface of the cured coating comprised prisms with blunt peaks that were 500 nm wide.

The relative abrasion damage AD_{R} caused by oscillating bead abrasion was measured to be 91% using the film in Example 1 as the reference, indicating superior abrasion resistance.

### Example 3

### A Light Directing Film Comprising Blunt Peaks 750 nm Wide

A light directing film was prepared using the materials and by the method described in Example 1, using a mold constructed as described in Example 2 but so that the surface of the cured coating comprised prisms with blunt peaks that were 750 nm wide.

The relative abrasion damage AD_{R} caused by oscillating bead abrasion was measured to be 43% using the film in Example 1 as the reference, indicating superior abrasion resistance. The threshold load for visual damage was measured to be 0.6 g, a significant improvement over the film in Example 1. In other words, an increase in load of greater than or equal to 100% was needed to produce a visible scratch. The on-axis luminance of the film was measured to be 98.3% of that of the film in Example 1, indicating a small decrease in luminance performance.

### Example 4

### A Light Directing Film Comprising Blunt Peaks 1,250 nm Wide

A light directing film was prepared using the materials and by the method described in Example 1, using a mold constructed as described in Example 2 but so that the surface of the cured coating comprised prisms with blunt peaks that were 1,250 nm wide.

The relative abrasion damage AD_{R} caused by oscillating bead abrasion was measured to be 25% using the film in Example 1 as the reference, indicating superior abrasion resistance. The threshold load for visual damage was measured to be 0.7 g by the procedure described above, a significant improvement over the film in Example 1. In other words, an increase in load of greater than or equal to 100% was needed to produce a visible scratch. The on-axis luminance of the film was measured to be 97.7% of that of the film in Example 1, indicating a small decrease in luminance performance.

### Example 5

### Another Comparative Example of a Light Directing Film without Blunt Prism Peaks

Light directing film was prepared by curing a UV curable acrylate coating following the same procedure as in Example 1, where the coating comprised the coating of Example 1 to which was added 15 pbw (parts by weight) hexafunctional urethane acrylate EBECRYL 8301 to further cross-link the coating, hereafter designated “Resin B.” The mold was constructed so that the surface of the cured coating comprised prisms with sharp peaks; essentially 0 nm radius.

The relative abrasion damage AD_{R} caused by oscillating bead abrasion was measured to be 54% using the film in Example 1 as the reference, indicating superior abrasion resistance attributable to the coating formulation. The threshold load for visual damage was measured to be 1.0 g, a significant improvement over the film in Example 1, again attributable to coating formulation. The on-axis luminance of the film was measured to be 96.7% of that of the film in Example 1, indicating a small decrease in luminance performance attributable to coating formulation.

### Example 6

### A Light Directing Film Comprising Blunt Peaks 500 nm Wide

A light directing film was prepared using the materials and by the method described in Example 5, using a mold constructed in accordance with Example 2 so that the surface of the cured coating comprised prisms with blunt peaks that were 500 nm wide.

The relative abrasion damage AD_{R} caused by oscillating bead abrasion was measured to be 89% using the film in Example 5 as the reference, indicating superior abrasion resistance attributable to the blunt tip.

### Example 7

### A Light Directing Film Comprising Blunt Peaks 750 nm Wide

A light directing film was prepared by the method described in Example 5, using a mold constructed as described in Example 2, but so that the surface of the cured coating comprised prisms with blunt peaks that were 750 nm wide.

The relative abrasion damage AD_{R} caused by oscillating bead abrasion was measured to be 37% using the film in Example 5 as the reference, indicating superior abrasion resistance attributable to the blunt tip. The on-axis luminance of the film was measured to be 99.3% of that of the film in Example 5, indicating a small decrease in luminance performance.

### Example 8

### A Light Directing Film Comprising Blunt Peaks 1,250 nm Wide

A light directing film was prepared by the method described in Example 5, using a mold constructed as described in Example 2, but so that he surface of the cured coating comprised prisms with blunt peaks that were 1250 nM wide.

The relative abrasion damage AD_{R} caused by oscillating bead abrasion was measured to be 28% using the film in Example 5 as the reference, indicating superior abrasion resistance attributable to the blunt tip. The threshold load for visual damage was measured to be 1.8 g by the procedure described above, a significant improvement over the film in Example 5. In other words, an increase in load of greater than or equal to 80% was needed to produce a visible scratch. The on-axis luminance of the film was measured to be 98.7% of that of the film in Example 5, indicating a small decrease in luminance performance.

Table 1 summarizes the test results for Examples 1-8.

| | | | | Abrasion (AD_{R}, | Abrasion (AD_{R}, | Threshold | Luminance | Luminance |
|---|---|---|---|---|---|---|---|---|
| Example | Resin | Tip (nm) | tip/pitch | % Ex 1) | % sharp) | Load (g) | (% Ex 1) | (% sharp) |
| 1 | A | 0 | 0.0% | 100% | 100% | 0.3 | 100.0% | 100.0% |
| 2 | A | 500 | 1.4% | 91% | 91% | | | |
| 3 | A | 750 | 2.0% | 43% | 43% | 0.6 | 98.3% | 98.3% |
| 4 | A | 1250 | 3.4% | 25% | 25% | 0.7 | 97.7% | 97.7% |
| 5 | B | 0 | 0.0% | 54% | 100% | 1 | 96.7% | 100.0% |
| 6 | B | 500 | 1.4% | 48% | 89% | | | |
| 7 | B | 750 | 2.0% | 20% | 37% | | 96.0% | 99.3% |
| 8 | B | 1250 | 3.4% | 15% | 28% | 1.8 | 95.4% | 98.7% |

The prism pitch for Examples 1-8 was 37 μm.

The unexpected result summarized in Table 1 is that a relative abrasion damage of 25% to 28% and a doubling of load to produce visible scratches could be achieved by blunting of prism tips by only 1,250 nm or 3.4% of the prism pitch. This improvement in abrasion resistance is achieved with only less than 2.5% reduction in luminance, again as compared to the same materials using a sharp tip prism. A relative abrasion damage of 37% to 43% could be achieved with a tip blunting of only 750 nm or 2.0% of prism pitch, with a loss in luminance of only 1% to 2%. A relative abrasion damage of about 90% could be achieved with a tip blunting of only 500 nm or 1.4% of the prism pitch. These magnitudes of tip blunting are comparable to the wavelength of visible and near-infrared light. Hence, at blunting in the order of magnitude of the wavelength of light, a substantial and expected improvement in abrasion (e.g., scratch) resistance is attained.

Magnitudes in the order of less than or equal to 2,000 nm (e.g., 5.4%) are far below many prior art teachings that scratch-resistant prismatic films require rounding of the prism tips on the order of 20% to 40% of the prism pitch. The reductions in abrasion damage achieved herein are of great significance in the end-use of prism films.

Ranges disclosed herein are inclusive and combinable (e.g., ranges of “up to 25 wt %, or, more specifically, 5 wt % to 20 wt %”, is inclusive of the endpoints and all intermediate values of the ranges of “5 wt % to 25 wt %,” etc.). “Combination” is inclusive of blends, mixtures, alloys, reaction products, and the like. Furthermore, the terms “first,” “second,” and the like, herein do not denote any order, quantity, or importance, but rather are used to distinguish one element from another, and the terms “a” and “an” herein do not denote a limitation of quantity, but rather denote the presence of at least one of the referenced item. The modifier “about” used in connection with a quantity is inclusive of the state value and has the meaning dictated by context, (e.g., includes the degree of error associated with measurement of the particular quantity). The suffix “(s)” as used herein is intended to include both the singular and the plural of the term that it modifies, thereby including one or more of that term (e.g., the film(s) includes one or more films). The notation “+10%” means that the indicated measurement can be from an amount that is minus 10% to an amount that is plus 10% of the stated value. Reference throughout the specification to “one embodiment”, “another embodiment”, “an embodiment”, and so forth, means that a particular element (e.g., feature, structure, and/or characteristic) described in connection with the embodiment is included in at least one embodiment described herein, and may or may not be present in other embodiments. In addition, it is to be understood that the described elements may be combined in any suitable manner in the various embodiments and are not limited to the specific combination in which they are discussed.

While the films have been described with reference to exemplary embodiments, it will be understood by those skilled in the art that various changes can be made and equivalents can be substituted for elements thereof without departing from the scope. In addition, many modifications can be made to adapt a particular situation or material to the teachings of the optical film without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A film, comprising:
a transparent substrate comprising a plurality of prism structures, wherein the prism structures have a blunt tip having a tip length of 250 nm to 2,000 nm.

2. The film of claim 1, wherein the tip length is 500 nm to 1,300 nm.

3. The film of claim 1, wherein the tip length is 500 nm to 1,000 nm.

4. The film of claim 1, wherein the tip length is 500 nm to 800 nm.

5. The film of claim 1, further comprising a relative abrasion damage of less than 50%, as compared to the same composition film with the same characteristic except without blunt prism tips, and determined in accordance with Equation 2.

6. The film of claim 5, further comprising a relative abrasion damage of less than 30%, as compared to the same composition film with the same characteristic except without blunt prism tips, and determined in accordance with Equation 2.

7. The film of claim 1, wherein prism has a virtual tip angle of the prism (Θ) of 70° to 120°.

8. The film of claim 1, further comprising a luminance reduction of less than or equal to 3% as compared to a luminance of an equivalent film with sharp prism tips.

9. The film of claim 8, wherein the luminance reduction is less than or equal to 2%.

10. The film of claim 1, wherein the load required to create a visible scratch (as is determined with the unaided eye in a dark room, from a viewing distance of 0.1 to 1 meters), is increased by greater than or equal to 80%, as compared to the same composition film with the same characteristic except without blunt prism tips.

11. The film of claim 1, wherein each prism structure has a lateral modulation in the w direction.

12. The film of claim 11, wherein each prism structure has the lateral modulation in the w direction of ±2% to ±20% of an average pitch of the prism structures.

13. The film of claim 1, wherein the prism structures have a valley with a rounded radius of 100 nm to 1,000 nm.

14. A film, comprising:
a transparent substrate comprising a plurality of prism structures, wherein the prism structures have a blunt tip having a tip length of 250 nm to 2,000 nm;
wherein the film has a relative abrasion damage of less than 30%, as compared to the same composition film with the same characteristic except without blunt prism tips, and determined in accordance with Equation 2; and
wherein a luminance of the film is reduced less than or equal to 5% as compared to a luminance of an equivalent film with sharp prism tips.

15. A backlight display comprising a light source and the film of claim 1.

16. A method for forming a master for a film, comprising:
ion beam etching a diamond tip to form a blunt tip having a tip length of 250 nm to 2,000 nm; and
forming negatives of prism structures into a master using the diamond tip.

17. The master of claim 16, wherein each prism structure has a lateral modulation in the w direction.

18. The master of claim 17, wherein each prism structure has a lateral modulation in the w direction of ±2% to ±20% of an average pitch of the prism structures.

19. A method for forming prism structures into the surface of a transparent substrate, comprising: contacting the master of claim 16 with a transparent substrate to form a light directing film having the prism structures with a blunt tip having a tip length of 250 nm to 2,000 nm.
